(19) United States
(12) Patent Application Publication
(10) Pub. No.: US 2007/0166931 A1
(43) Pub. Date: Jul. 19, 2007

(54) Methods of Manufacturing A Semiconductor Device for Improving the Electrical Characteristics of A Dielectric Film

(76) Inventors: Hong-Bae Park, Gyeonggi-do (KR); Hag-Ju Cho, Yongin-si (KR); Yu-Gyun Shin, Seongnam-si (KR); Sang-Bom Kang, Seoul (KR)

Correspondence Address: Frank Chau, Esq.;F. CHAU & ASSOCIATES, LLC, 130 Woodbury Road, Woodbury, NY, 11797, US

(21) Appl. No.: 11/567,971

(22) Filed: Dec. 7, 2006

(30) Foreign Application Priority Data
Dec. 7, 2005 (KR) 2005-118884

(51) Int. Cl. H01L 21/336

(52) U.S. Cl. 438/287

(57) ABSTRACT

A method of manufacturing a semiconductor device includes depositing a high-dielectric film on a semiconductor substrate and performing an oxygen plasma treatment on the high-dielectric film deposited on the semiconductor substrate. The method further includes forming an electrode on the oxygen-plasma treated high-dielectric film.

### CROSS-REFERENCE TO RELATED APPLICATIONS

This U.S. non-provisional patent application claims priority to Korean Patent Application 2005-118884 filed on Dec. 7, 2005, the disclosure of which is hereby incorporated by reference herein in its entirety.

### BACKGROUND

The present disclosure relates to methods for manufacturing semiconductor devices, and in particular relates to methods for manufacturing semiconductor devices which provide improved electrical characteristics for dielectric films.

With higher integration density and larger storage capacity, gate insulation films of semiconductor devices are being manufactured thinner in thickness. Moreover, silicon oxide (SiO₂) films are typically used as gate insulation films because of their beneficial properties with respect to thermal stability, reliability and are also convenient to manufacture. However, as silicon oxide films have a dielectric constant of about 3.9 which is not considered to be a relatively high dielectric constant, these silicon oxide films typically need to be scaled down in thickness. There is a limit, however, to how much a silicon oxide film may be physically scaled down in thickness due to the possibility of a steep increase in the amount of leakage current.

Accordingly, high-dielectric films suitable for use as gate insulation films which may replace such conventional silicon oxide films are being investigated. If such high-dielectric films are used as a gate insulation film, it is permissible to form them with a larger thickness than the thicknesses of he conventional silicon oxide films under the same capacitance, thereby reducing the amount of leakage current therein. There are various materials which may be used as high-dielectric films, such as, for example, (Ba_{X}, Sr_{1-X})TiO₃(e.g. barium strontium titanate (BST), titanium oxide (tiO₂), tantalum oxide (Ta₂O₅), aluminum oxide (Al₂O₃), zirconium oxide (ZrO₂), Zr silicate, hafnium oxide (HfO₂), or Hf silicate.

However, there may still be difficulties associated with using such high-electric films as the gate insulation film. For example, when a film of BST, TiO₂, or TaO₂ is directly deposited on a silicon substrate, the interface characteristics with the substrate may worsen to thereby increase the amount of leakage current therethrough. Moreover, as a result, the interface trap charge density may also increase to thereby significantly lower the mobility of carriers. Furthermore, using a high-dielectric film by itself may make it difficult to stabilize the threshold voltage of a field effect transistor. Thus, there is a need for a method for manufacturing semiconductor devices which provides improved electrical characteristics for dielectric films.

### SUMMARY OF THE INVENTION

Exemplary embodiments of the present invention provide a method of manufacturing a semiconductor device which provides improved electrical characteristics for a dielectric film.

In accordance with an exemplary embodiment of the present invention, a method of manufacturing a semiconductor device is provided. This method includes depositing a high-dielectric film on a semiconductor substrate and performing an oxygen plasma treatment on the high-dielectric film deposited on the semiconductor substrate. The method further includes forming an electrode on the oxygen plasma treated high-dielectric film.

In an exemplary embodiment, the semiconductor substrate may be formed of a material comprising silicon (Si), germanium (Ge), or silicon-germanium (SiGe). The high-dielectric film may be made of a metal oxide or a metal silicate. The method may further comprise forming an interface layer on the semiconductor substrate before depositing the high-electric film. The interface layer may be formed of silicon oxide or silicon oxynitride. The oxygen plasma treatment may be carried out by remote oxygen plasma treatment or direct oxygen plasma treatment. The electrode may be made of at least one material selected from the group consisting of doped polysilicon, metal, conductive metal nitride, and metal silicide. The method may further comprise forming a capping layer on the oxygen-plasma treated high-dielectric film after processing the oxygen plasma treatment. The capping layer may be formed of silicon nitride. The method may further comprise processing a supplementary oxygen plasma treatment after forming the capping layer. The method may further comprise performing a nitrification treatment to the high-dielectric film before or after processing the oxygen plasma treatment.

In accordance with an exemplary embodiment of the present invention, a method of manufacturing a semiconductor device comprises is provided. The method includes depositing a multi-level high-dielectric film including a plurality of high-dielectric layers stacked on a semiconductor substrate and performing an oxygen plasma treatment on the multi-level high-dielectric film deposited on the semiconductor substrate. The method further includes forming an electrode on the oxygen plasma treated multi-level high-dielectric film.

In an exemplary embodiment, the oxygen plasma treatment may be carried out after depositing all the plurality of high-dielectric layers of the multi-level high-dielectric film. Otherwise, the oxygen plasma treatment may be carried out after depositing each of the plurality of high-dielectric layers of the multi-level high-dielectric film.

### BRIEF DESCRIPTION OF THE FIGURES

Exemplary embodiments of the present invention can be understood in more detail from the following description taken in conjunction with the accompanying drawings, in which:

FIGS. 1A through 1C are sectional views illustrating processing steps for manufacturing a semiconductor device in accordance with an exemplary embodiment of the invention;

FIGS. 2A through 2D are sectional views illustrating processing steps for manufacturing a semiconductor device in accordance with an exemplary embodiment of the invention;

FIGS. 3A through 3C are sectional views illustrating processing steps for manufacturing a semiconductor device in accordance with an exemplary embodiment of the invention;

FIGS. 4A through 4D are sectional views illustrating processing steps for manufacturing a semiconductor device in accordance with an exemplary embodiment of the invention; and

FIG. 5 is a graphic view showing a characteristic of leakage current in a high-dielectric film treated by oxygen plasma treatment in accordance with an exemplary embodiment of the invention.

### DETAILED DESCRIPTION OF THE EXEMPLARY EMBODIMENTS

Exemplary embodiments of the present invention will be described below in more detail with reference to the accompanying drawings. The present invention may, however, be embodied in different forms and should not be constructed as limited to the exemplary embodiments set forth herein.

It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

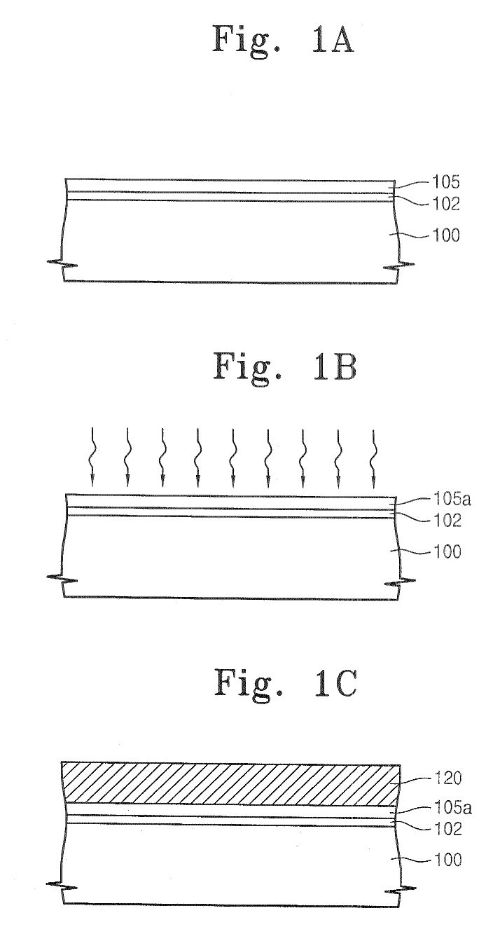

FIGS. 1A through 1C are sectional views illustrating processing steps for manufacturing a semiconductor device in accordance with a first exemplary embodiment of the invention.

Referring to FIG. 1A, a high-dielectric film 105 is deposited on a semiconductor substrate 100. The semiconductor substrate 100 may be made of, for example, germanium (Ge), silicon germanium (SiGe), or silicon (Si). The high-dielectric film 105 is higher than a silicon oxide film in dielectric constant. For example, the high-dielectric film 105 is preferred to be formed of a material selected from a metal oxide and a metal silicate. For instance, the high-dielectric film 105 may contain hafnium silicate oxide (HfSiO) formed by means of chemical vapor deposition (CVD) or atomic layer deposition (ALD). Before depositing the high-dielectric film 105, an interface layer 102 may be formed on the surface of the semiconductor substrate 100. The interface layer 102 is interposed between the high-dielectric film 105 and the semiconductor substrate 100, functioning to enhance electrical characteristics, e.g., increasing the mobility of electrons (or holes) in a channel region. The interface layer 102 is made of an insulative material. As an example, the interface layer 102 may be formed of silicon oxide (SiO₂) or silicon oxynitride (SiON) by means of various processing ways (e.g., thermal oxidation, CVD, ALD, or a composite manner with them). It is preferred for the interface layer 102 to be formed at a thickness of about 5 to about 20 angstroms (Å).

Referring to FIG. 1B, it illustrates a feature of conducting oxygen (O₂) plasma treatment. In detail, the oxygen plasma treatment is carried out on the semiconductor substrate 100 having the high-dielectric film 105. In the figures, the reference number ‘105’ denotes the deposited high-dielectric film, while ‘105a’ denotes the oxygen-plasma treated high-dielectric film. This process of oxygen plasma treatment may be carried out in the type of remote oxygen plasma or direct oxygen plasma treatment. The oxygen plasma treatment may be carried out under the atmosphere with oxygen of about 1 SLM (standard liters per minute) and nitrogen of about 0.12 SLM. Gas supplying temperature is preferred to be at about 25 to about 300 Celsius (°C.), including room temperature. More preferably, it is proper to carry out this process under about 100° C. A power rate is set at about 100 to about 400 watts (W) for about 40 to about 80 seconds.

The oxygen plasma treatment cures the high-dielectric film 105. Thereby, the oxygen-plasma treated high-dielectric film 105a provides improved leakage current properties. Namely, the leakage current through the oxygen-plasma treated high-dielectric film 105a is reduced to the minimum degree. In forming the interface layer 102, it is significant to control processing conditions of the oxygen plasma treatment so as not to raise the thickness thereof.

Before or after conducting the oxygen plasma treatment, a nitrification treatment is performed on the semiconductor substrate 100 including the high-dielectric film 105 or 105a. This nitrification treatment may contribute to improve the thermal stability of the high-dielectric film 105. The nitrification treatment may be carried out by means of a thermal nitrification process at a temperature of about 700 to about 1000° C. or a plasma nitrification process under a temperature of less than about 500° C. The thermal nitrification process may be performed with ammonia (NH₃) gas at a temperature of about 700 to about 1000° C. under a pressure of about 1 to about 100 Torr for about 30 seconds through about 2 minutes. The plasma nitrification process may be performed at a temperature less then about 500° C. under a pressure of about 5 to about 100 m Torr for about 30 seconds through about 5 minutes.

When a gate electrode subsequently formed is made of polysilicon doped with impurities, it is preferred to conduct the nitrification treatment on the oxygen-plasma treated high-dielectric film 105a. If the nitrification treatment is carried out before the oxygen plasma treatment, it reduces the concentration of nitrogen in the oxygen-plasma treated high-dielectric film 105a and weakens bonding forces among atoms, because of disturbance in the combination between nitrogen and atoms of the high-dielectric film 105, by which impurities of the gate electrode may be diffused through the high-dielectric film 105a.

Otherwise, when the gate electrode is made of a conductive film (e.g., conductive metallic nitride such as titanium nitride or tantalum nitride) or metal (e.g., tungsten or molybdenum), except the doped polysilicon, the nitrification treatment may be carried out before or after the oxygen plasma treatment. After the nitrification treatment, a high-temperature thermal process may be conducted under a temperature of about 800 to about 1100° C. to enhance the electrical characteristics of the high-dielectric film 105 or 105a.

Referring to FIG. 1C, an electrode 120 is formed on the high-dielectric film 105a. The electrode 120 is made of at least one material selected from doped polysilicon, metal (e.g., tungsten or molybdenum), conductive metal nitride (e.g., titanium nitride or tantalum nitride), and metal (e.g., tungsten silicide or cobalt silicide). The electrode 120 may be correspondent with a gate electrode of a field effect transistor.

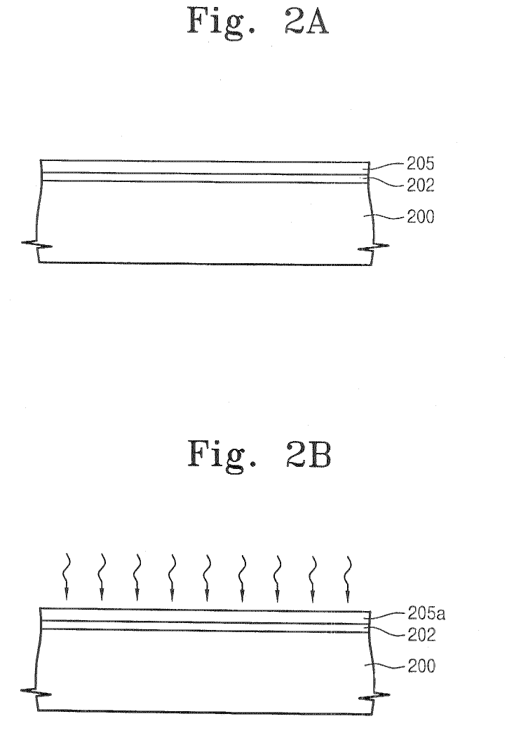

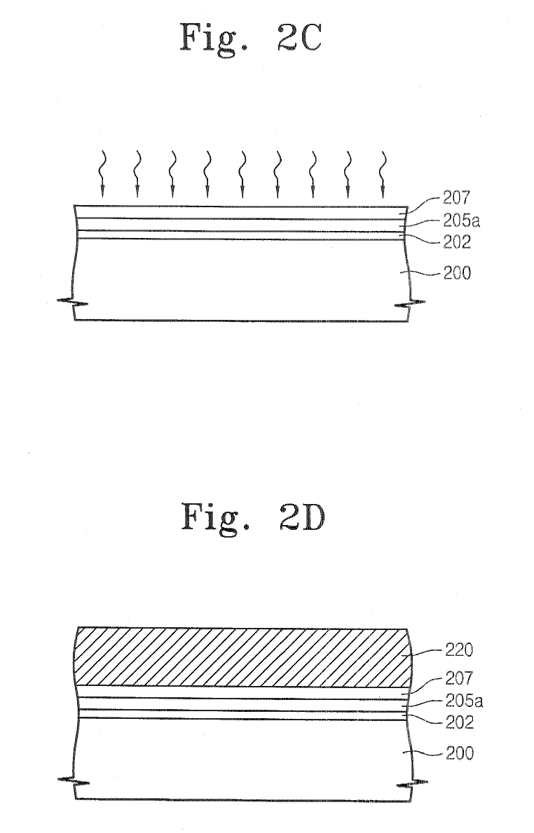

FIGS. 2A through 2D are sectional views illustrating processing steps for manufacturing a semiconductor device in accordance with a second exemplary embodiment of the invention. This exemplary embodiment is practiced by additionally depositing a thin capping layer after completing the oxygen plasma treatment, which will be described as follows.

Referring to FIG. 2A, a high-dielectric film 205 is deposited on a semiconductor substrate 200. The semiconductor substrate 200 may be made of, for example germanium (Ge), silicon germanium (SiGe), or silicon (Si). The high-dielectric film 205 is higher than a silicon oxide film in dielectric constant. For example, the high-dielectric film 205 is preferred to be formed of a material selected from a metal oxide and a metal silicate. For instance, the high-dielectric film 205 may contain hafnium silicate oxide (HfSiO) formed by means of CVD or ALD. Additionally, an interface layer 202 of an insulative material may be formed on the surface of the semiconductor substrate 200. The interface layer 202 is interposed between the high-dielectric film 205 and the semiconductor substrate 200, functioning to enhance electrical characteristics, e.g., increasing the mobility of electrons (or holes) in a channel region. The interface layer 202 may be formed of silicon oxide (SiO₂) or silicon oxynitride (SiON) by means of various processing ways (e.g., thermal oxidation, CVD, ALD, or a composite manner with them). Here, it is preferred for the interface layer 202 to be formed to a thickness of about 5 to about 20 Å.

Referring to FIG. 2B, the oxygen plasma treatment is carried out on the semiconductor substrate 200 having the high-dielectric film 205. In the figures, the reference number ‘205’ denotes the deposited high-dielectric film before the oxygen plasma treatment, while ‘205a’ denotes the oxygen-plasma treated high-dielectric film. The oxygen plasma treatment cures the high-dielectric film 205a. The oxygen plasma treatment cures the high-dielectric film 205a to thereby minimize the leakage current through the oxygen-plasma treated high-dielectric film 205a.

This process of oxygen plasma treatment may be carried out in the same manner as the first exemplary embodiment. Namely, the oxygen plasma treatment may be conducted using, for example, a remote oxygen plasma or a direct oxygen plasma treatment. The oxygen plasma treatment may be carried out under the atmosphere with oxygen of about 1 SLM (standard liters per minute) and nitrogen of about 0.12 SLM. Gas supplying temperature is preferred to be about 25 to about 300° C. including room temperature. More preferably, it is proper to carry out this process under about 100° C. A power rate is set at about 100 to about 400W for about 40 to about 80 seconds. In forming the interface layer 202, it is significant to control processing conditions of the oxygen plasma treatment so as not to raise the thickness thereof.

Before or after conducting the oxygen plasma treatment, a nitrification treatment is performed on the high-dielectric film 205 or 205a. This nitrification treatment may contribute to improve the thermal stability of the high-dielectric film 205. The nitrification treatment may be carried out by means of a thermal nitrification process at a temperature of about 700 to about 1000° C. or a plasma nitrification process under a temperature of less than about 500° C. The thermal nitrification process may be performed with ammonia (NH₃) gas at a temperature of about 700 to about 1000° C. under a pressure of about 1 to about 100 Torr for about 30 seconds through about 2 minutes. The plasma nitrification process may be performed at a temperature of less then about 500° C. under a pressure of about 5 to about 100 mTorr for about 30 seconds through about 5 minutes.

When a gate electrode subsequently formed is made of polysilicon doped with impurities, it is preferred to conduct the nitrification treatment on the oxygen-plasma treated high-dielectric film 205a. Namely, the nitrification treatment may be conducted after the oxygen plasma treatment. If the nitrification treatment is carried out before the oxygen plasma treatment, the concentration of nitrogen in the oxygen-plasma treated high-dielectric film 205a may be reduced and the bonding forces among atoms may be weakened, because of disturbance in the combination between nitrogen and atoms of metal oxide or metal silicate, by which impurities (or dopants) of the gate electrode may diffuse through the high-dielectric film 205a to thereby result in the deterioration of electrical characteristic of the high-dielectric film 205a. On the other hand, when the gate electrode is made of a conductive material containing metal, the nitrification treatment may be carried out before or after the oxygen plasma treatment.

After the nitrification treatment, a high-temperature thermal process under a temperature of about 800 to about 1100° C. may be conducted to enhance the electrical characteristics of the high-dielectric film 205 or 205a.

Referring to FIG. 2C, a capping layer 207 is deposited on the high-electric film 205a. The capping layer 207 is made of an insulative material. For instance, the capping layer 207 may be formed of silicon nitride (SiN). The capping layer 207 functions to prevent the high-dielectric film 205a from reacting with an electrode that is to be formed in the subsequent step. After forming the capping layer 207, a supplementary oxygen plasma treatment may be conducted to enhance the characteristic of the capping layer 207 as illustrated. The supplementary oxygen plasma treatment may be processed under the same condition as the aforementioned oxygen plasma treatment.

Referring to FIG. 2D, an electrode 220 is formed on the capping layer 207. The electrode 220 may be made of at least one material selected from, for example, doped polysilicon, metal (e.g., tungsten or molybdenum), conductive metal nitride (e.g., titanium nitride or tantalum nitride), and metal (e.g., tungsten silicide or cobalt silicide).

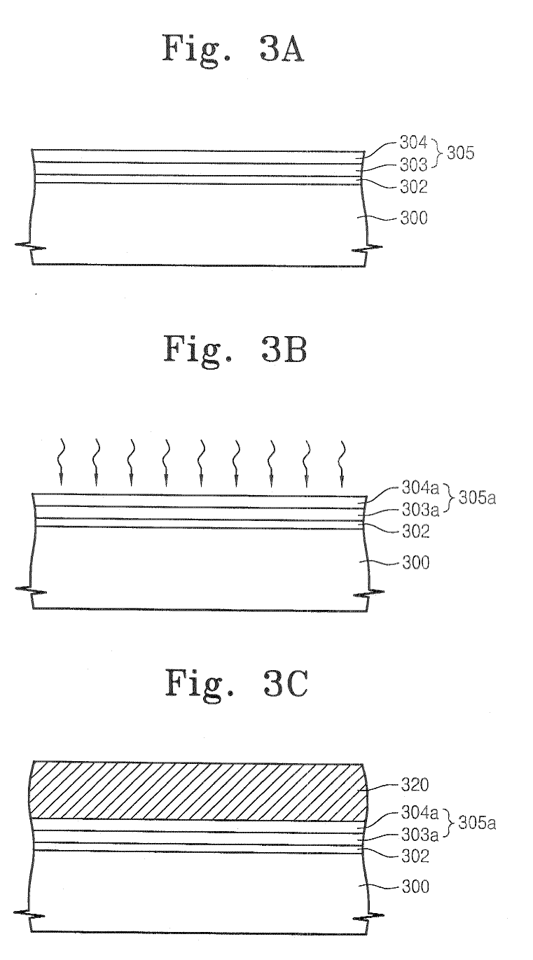

FIGS. 3A through 3C are sectional views illustrating processing steps for manufacturing a semiconductor device in accordance with a third exemplary embodiment of the invention. In this exemplary embodiment, the high-dielectric film is composed of a composite with more two layers, different from the first or second embodiment in which the high-dielectric film is formed of a single layer.

Referring to FIG. 3A, a multi-level high-dielectric film 305 is deposited on a semiconductor substrate 300 that is made of, for example, germanium (Ge), silicon germanium (SiGe), or silicon (Si). The multi-level high-dielectric film 305 is higher than a silicon oxide film in dielectric constant. The multi-level high-dielectric film 305 is formed of a composite layer stacked with pluralities of layers selected from a metal oxide and a metal silicate. In more detail, the multi-level high-dielectric film 305 may include first and second high-dielectric layers 303 and 304, which are stacked in sequence. The first high-dielectric layer 303 may be formed of, for example, one material selected from a metal oxide or a metal silicate. The second high-dielectric layer 304 may be also formed of, for example, one material selected from a metal oxide or a metal silicate. According to an exemplary embodiment, one of the first and second high-dielectric layers 303 and 304 may be made of metal oxide, while the other may be made of metal silicate. In addition, the multi-level high-dielectric film 305 may be consulted in an alternately stacked structure with the first and second high-dielectric layers 303 and 304. Further, the multi-level high-dielectric film 305 may include an insulative material that is interposed between the first and second high-dielectric layers 303 and 304 so as to enhance the interface characteristic thereof. For instance, the first high-dielectric layer 303 may contain hafnium oxide HfO formed by means of CVD or ALD, while the second high-dielectric layer 304 may contain hafnium silicate oxide (HfSiO) formed by means of CVD or ALD.

An additional processing step may be conducted for forming an interface layer 302 of insulative material that is interposed between the multi-level high-dielectric film 305 and the semiconductor substrate 300, thereby enhancing the interface characteristic therebetween to increase the mobility of electrons (or holes) in a channel region. The interface layer 302 may be made of, for example, silicon oxide (SiO₂) or silicon oxynitride (SiON). The interface layer 302 may be formed to a thickness of about 5 to about 20 Å.

Referring to FIG. 3B, it illustrates a feature of conducting oxygen plasma treatment. In detail, the oxygen plasma treatment is carried out on the semiconductor substrate 300 having the multi-level high-dielectric film 305. In the figures, the reference number ‘305’ denotes the deposited multi-level high-dielectric film, while ‘305a’ denotes the oxygen-plasma treated multi-level high-dielectric film. The multi-level high-dielectric film 305a, which has been processed by the oxygen plasma treatment, includes first and second high-dielectric layers 303a and 304a, stacked in sequence, that have been plasma-treated.

This process of oxygen plasma treatment may be carried out in the same manner as the first or second exemplary embodiment. In other words, the oxygen plasma treatment may be processed using, for example, remote oxygen plasma or direct oxygen plasma treatment. The oxygen plasma treatment may be carried out under the atmosphere with oxygen of about 1 SLM and nitrogen of about 0.12 SLM. Gas supplying temperature is preferred to be about 25 to about 300° C., including room temperature. For example, this process may be carried out under about 100° C. A power rate is set at about 100 to about 400W for about 40 to about 80 seconds. In forming the interface layer 302, it is significant to control processing conditions of the oxygen plasma treatment so as not to raise the thickness thereof.

The oxygen plasma treatment may include first and second steps of oxygen plasma treatment. The first oxygen plasma treatment begins after depositing the first high-dielectric layer 303, and the second oxygen plasma treatment begins after depositing the second high-dielectric layer 304. As also aforementioned, the oxygen plasma treatment may be carried out once after continuously depositing the first and second high-electric layers 303 and 304. The first and second oxygen plasma treatment steps may be carried out in the aforementioned manner of oxygen plasma treatment.

Before or after conducting the oxygen plasma treatment, a nitrification treatment for improving thermal stability of the multi-level high-dielectric film 305 and 305a may be performed. The nitrification treatment may be carried out by means of a thermal nitrification process at a temperature of about 700 to about 1000° C. or a plasma nitrification process under a temperature less than about 500° C. When a gate electrode subsequently formed is made of polysilicon doped with impurities, the nitrification treatment may be conducted after completing the oxygen plasma treatment. This is because of the reason described relevant to the first or second exemplary embodiment. The thermal nitrification process may be performed with ammonia (NH₃) gas at a temperature of about 700 to about 1000° C. under a pressure of about 1 to about 100 Torr for about 30 seconds through about 2 minutes. The plasma nitrification process may be performed at a temperature less then about 500° C. under a pressure of about 5 to about 100 mTorr for about 30 seconds through about 5 minutes. After completing the nitrification treatment, a high-temperature thermal operation may be processed at a temperature of about 800 to about 1100° C. to improve the electrical characteristics of the multi-level high-dielectric film 305 or 305a.

Referring to FIG. 3C, an electrode 320 is formed on the multi-level high-dielectric film 305a to thereby complete the structure of a metal-insulator-semiconductor (MLS). The electrode 320 is made of the same material as the electrodes 120 and 220 shown in the first and second exemplary embodiments as aforementioned.

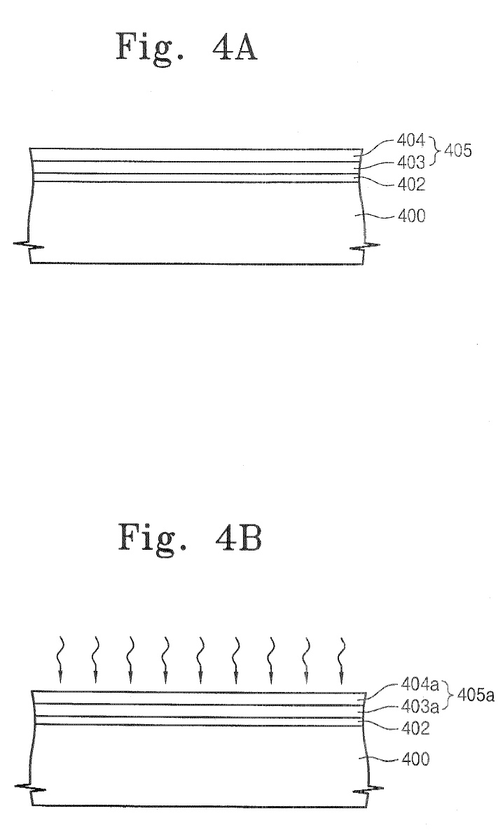

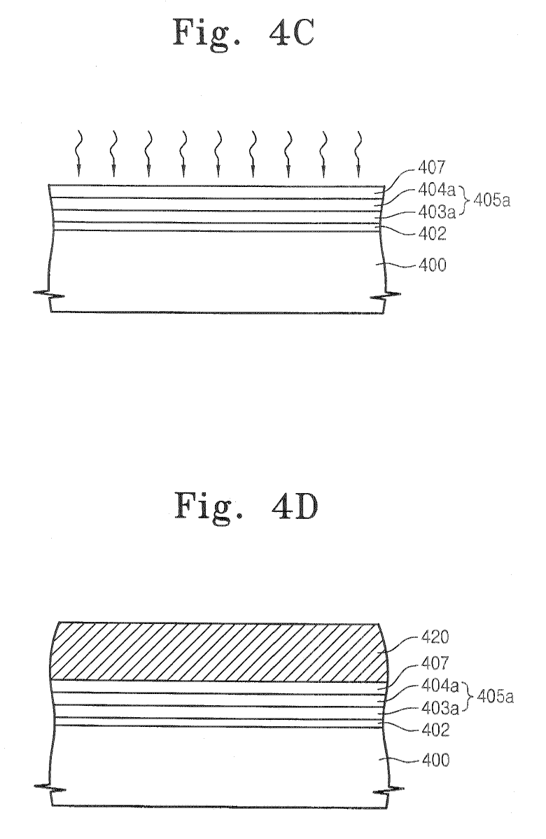

FIGS. 4A through 4D are sectional views illustrating processing steps for manufacturing a semiconductor device in accordance with a fourth exemplary embodiment of the invention. In this exemplary embodiment, while the high-dielectric film is formed of a composite layer like the third exemplary embodiment, there is further provided a step of depositing a thin capping layer after processing the oxygen plasma treatment.

Referring to FIG. 4A, a multi-level high-dielectric film 405 is deposited on a semiconductor substrate 400 that is made of, for example, germanium (Ge), silicon germanium (SiGe), or silicon (Si). The multi-level high-dielectric film 405 is higher than a silicon oxide film in dielectric constant. For example, the multi-level high-dielectric film 405 is formed of a composite layer stacked with pluralities of layers selected from a metal oxide and a metal silicate. In more detail, the multi-level high-dielectric film 405 may include first and second high-electric layers 403 and 404 which are stacked in sequence. The first high-dielectric layer 403 may be formed of, for example, one material selected from a metal oxide or a metal silicate. The second high-dielectric layer 404 may be also formed of, for example, one material selected from a metal oxide or a metal silicate. According to an exemplary embodiment, one of the first and second high-dielectric layers 403 and 404 may be made of a metal oxide, while the other may be made of a metal silicate. In addition, the multi-level high-dielectric film 405 may be constituted in an alternately stacked structure with the first and second high-dielectric layers 403 and 404. Further, the multi-level high-dielectric film 405 may include an insulative material that is interposed between the first and second high-dielectric layers 303 and 304 so as to enhance the interface characteristic thereof. For instance, the first high-dielectric layer 403 may contain hafnium oxide HfO formed by means of CVD or ALD, while the second high-dielectric layer 404 may contain hafnium silicate oxide (HfSiO) formed by means of CVD or ALD.

In addition, a further processing step of forming an interface layer 402 of insulative material that is interposed between the multi-level high-dielectric film 405 and the semiconductor substrate 400 may be conducted. The interface layer 402 functions to enhance the interface characteristic therebetween to increase the mobility of electrons (or holes) in a channel region. The interface layer 402 may be made of, for example, silicon oxide (SiO₂) or silicon oxynitride (SiON) by means of various processing ways.

Referring to FIG. 4B, it illustrates a feature of conducting oxygen plasma treatment. In detail, the oxygen plasma treatment is carried out on the semiconductor substrate 400 having the multi-level high-dielectric film 405. In the figures, the reference number ‘405’ denotes the deposited multi-level high-dielectric film, while ‘405a’ denotes the oxygen-plasma treated multi-level high-dielectric film. The multi-level high-dielectric film 405 a, which has been processed by the oxygen plasma treatment, includes first and second high-dielectric layers 403a and 404a, stacked in sequence, which have been plasma-treated.

This process of oxygen plasma treatment may be carried out in the same manner with the first, second, or third exemplary embodiment. In other words, the oxygen plasma treatment may be processed using remote oxygen plasma or direct oxygen plasma treatment. The oxygen plasma treatment may be carried out under the atmosphere with oxygen of about 1 SLM and nitrogen of about 0.12 SLM. Gas supplying temperature is preferred to be about 25 to about 300° C., including room temperature. More preferably, it is proper to carry out this process under about 100° C. A power rate is set at about 100 to about 400W for about 40 to about 80 seconds. In forming the interface layer 402, it is significant to control processing conditions of the oxygen plasma treatment so as not to raise the thickness thereof.

The oxygen plasma treatment may include first and second steps of oxygen plasma treatment. The first oxygen plasma treatment begins after depositing the first high-dielectric layer 403, and the second oxygen plasma treatment begins after depositing the second high-dielectric layer 404. As also aforementioned, the oxygen plasma treatment may be carried out once after continuously depositing the first and second high-electric layers 403 and 404. The first and second oxygen plasma treatment steps may be carried out in the aforementioned manner of oxygen plasma treatment.

Before or after conducting the oxygen plasma treatment, it is proper to perform a nitrification treatment for improving the thermal stability of the multi-level high-dielectric film 305 and 305a. The nitrification treatment may be carried out by means of a thermal nitrification process at a temperature of about 700 to about 1000° C. or a plasma nitrification process under a temperature less than about 500° C. When a gate electrode subsequently formed is made of polysilicon doped with impurities, it is preferred to conduct the nitrification treatment after completing the oxygen plasma treatment. This is because of the reason described relevant to the first or second exemplary embodiment. The thermal nitrification process may be performed with ammonia (NH₃) gas at a temperature of about 700 to about 1000° C. under a pressure of about 1 to about 100 Torr for about 30 seconds through about 2 minutes. The plasma nitrification process may be performed at a temperature less then about 500° C. under a pressure of about 5 to about 100 mTorr for about 30 seconds through about 5 minutes. After completing the nitrification treatment, a high-temperature thermal operation may be processed at a temperature of about 800 to about 1100° to improve the electrical characteristics of the multi-level high-dielectric film 405 or 405a.

FIG. 4C illustrates a feature of forming a capping layer in the semiconductor device. Referring to FIG. 4C, a capping layer 407 is deposited on the multi-level high-electric film 405a. The capping layer 407 is made of an insulative material. For instance, the capping layer 407 may be formed of silicon nitride (SiN). The capping layer 407 functions to prevent the multi-level high-dielectric film 405a from reacting with an electrode that is to be formed in the subsequent step. After forming the capping layer 407, a supplementary oxygen plasma treatment may further be conducted to enhance the characteristic of the capping layer 407 as illustrated. The supplementary oxygen plasma treatment may be processed under the same conditions as the aforementioned oxygen plasma treatment.

Referring to FIG. 4D, an electrode 420 is formed on the capping layer 207 to thereby complete the structure of the metal-insulator-semiconductor (MIS). The electrode 420 is correspondent with a gate electrode of a field effect transistor. The electrode 420 is made of the same material as the electrodes 120 and 220 shown in the first and second exemplary embodiments as aforementioned.

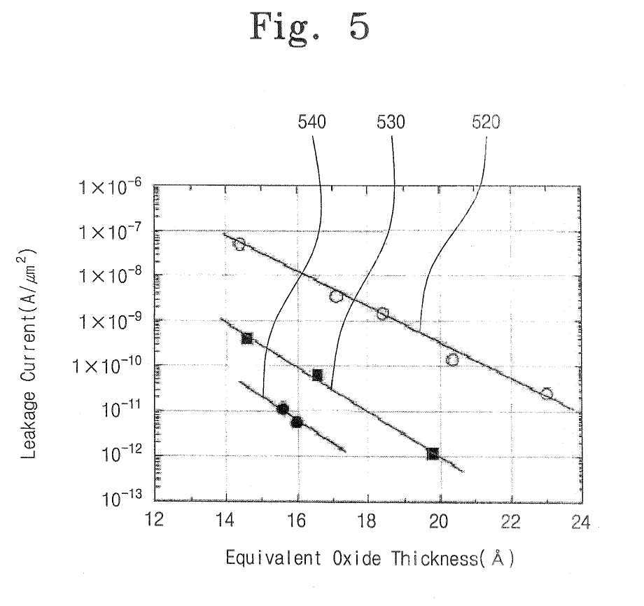

FIG. 5 is a graphic view showing a characteristic of leakage current in a high-dielectric film treated by oxygen plasma treatment in accordance with an exemplary embodiment of the invention.

Referring to FIG. 5, first, second, and third samples were prepared and the leakage current characteristics of the high-dielectric films for each of these samples was determined. The first samples were fabricated including field effect transistors whose gate insulation films were each formed of silicon oxide. In the first samples, the gate insulation films of silicon oxide were different in thickness from each other. The second samples were fabricated including field effect transistors, where each gate insulation film was formed in a single layer of hafnium silicate oxide. Also in the second samples, the gate insulation films of the single hafnium silicate oxide layers were different in thickness from each other. The third samples were fabricated including field effect transistors whose gate insulation films were each formed of dual high-dielectric films. There, the dual high-dielectric films of the third samples were processed by the oxygen plasma treatment according to exemplary embodiments of the invention. Namely, there was no oxygen plasma treatment to the second samples, but the third samples.

In the graph of the FIG. 5, the X-axis indicates the thickness of equivalent oxide films while the Y-axis indicates the amounts of leakage currents. A first plot 520 represents a tendency of leakage currents to the thickness of equivalent oxide films in the first samples, while a second plot 530 represents a tendency of leakage currents to the thickness of equivalent oxide films in the second samples. Moreover, a third plot 540 represents a tendency of leakage currents to the thickness of the same equivalent oxide films, which have been processed by the oxygen plasma treatment, in the third samples. As can be seen from FIG. 5, the amount of leakage current is smallest for the thickness of the equivalent oxide films belonging to the third samples that have been processed by the oxygen plasma treatment according to exemplary embodiments of the invention.

In the aforementioned exemplary embodiments, the electrodes 120, 220, 320, and 420 are illustrated as being used for gate electrodes. But, the high-dielectric films 105a, 205a, 305a, and 405a may be used as dielectric films of capacitors, or insulation films between floating and control gates of a flash memory device. The electrodes 120, 220, 320, and 420, which are associated with the high-dielectric films 105a, 205a, 305a, and 405a used as the dielectric films of the capacitors (e.g., in DRAMs), are correspondent with top electrodes of the capacitors, and the substrates 100, 200, 300, and 400 may be correspondent with storage electrodes of the capacitors. The electrodes 120, 220, 320, and 420, which are associated with the high-dielectric films 105a, 205a, , 305a, and 405a used as the insulation films between the floating and control gates of the flash memory device, are correspondent with the control gate electrodes thereof, and the semiconductor substrates 100, 200, 300, and 400 may be correspondent with the floating gates thereof.

Accordingly, the exemplary embodiments of the invention are able to improve the electrical characteristics, e.g., a leakage current characteristic, by processing the oxygen plasma treatment on the high-dielectric film that may be employed as a gate dielectric film of a next-generation transistor. Moreover, as the characteristic of leakage current is significantly advanced by processing the oxygen plasma treatment on the composite high-dielectric film, e.g., more than dual layers, as well as on the single layer, it is possible to scale the equivalent oxide thickness.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of manufacturing a semiconductor device, comprising:
depositing a high-dielectric film on a semiconductor substrate;
performing an oxygen plasma treatment on the high-dielectric film deposited on the semiconductor substrate; and
forming an electrode on the oxygen-plasma treated high-dielectric film.

2. The method as set forth in claim 1, wherein the semiconductor substrate is formed of a material comprising one of silicon (Si), germanium (Ge), or silicon-germanium (SiGe).

3. The method as set forth in claim 1, wherein the high-dielectric film is made of a material comprising a metal oxide or a metal silicate.

4. The method as set forth in claim 1, which further comprises: forming an interface layer on the semiconductor substrate before depositing the high-dielectric film.

5. The method as set forth in claim 4, wherein the interface layer is formed of a material comprising silicon oxide or silicon oxynitride.

6. The method as set forth in claim 1, wherein the oxygen plasma treatment is carried out by remote oxygen plasma treatment or direct oxygen plasma treatment.

7. The method as set forth in claim 1, wherein the electrode is made of a material comprising at least one of doped polysilicon, metal, conductive metal nitride, or metal silicide.

8. The method as set forth in claim 1, which further comprises: forming a capping layer on the oxygen-plasma treated high-dielectric film after performing the oxygen plasma treatment.

9. The method as set forth in claim 8, wherein the capping layer comprises silicon nitride.

10. The method as set forth in claim 8, which further comprises: performing a supplementary oxygen plasma treatment after forming the capping layer.

11. The method as set forth in claim 1, which further comprises: performing a nitrification treatment on the high-dielectric film before or after performing the oxygen plasma treatment.

12. A method of manufacturing a semiconductor device, comprising:
depositing a multi-level high-dielectric film comprising a plurality of high-dielectric layers stacked on a semiconductor substrate;
performing an oxygen plasma treatment on the multi-level high-dielectric film deposited on the semiconductor substrate; and
forming an electrode on the oxygen plasma treated multi-level high-dielectric film.

13. The method as set forth in claim 12, wherein the oxygen plasma treatment is carried out after depositing all of the plurality of high-dielectric layers of the multi-level high-dielectric film.

14. The method as set forth in claim 12, wherein the oxygen plasma treatment is carried out after depositing each of the plurality of high-dielectric layers of the multi-level high-dielectric film.

15. The method as set forth in claim 12, wherein the oxygen plasma treatment is carried out by remote oxygen plasma treatment or direct oxygen plasma treatment.

16. The method as set forth in claim 12, wherein the electrode is made of a material comprising at least one of doped polysilicon, metal, conductive metal nitride, or metal silicide.

17. The method as set forth in claim 12, wherein the semiconductor substrate is formed of a material comprising silicon (Si), germanium (Ge), or silicon-germanium (SiGe).

18. The method as set forth in claim 12, wherein each of the high-dielectric layers included in the multi-level high-dielectric film is made of a material comprising a metal oxide or a metal silicate.

19. The metal as set forth in claim 12, which further comprises: forming an interface layer on the semiconductor substrate before depositing the multi-level high-dielectric film.

20. The method as set forth in claim 12, which further comprises: forming a capping layer on the oxygen-plasma treated multi-level high-dielectric film after performing the oxygen plasma treatment.

21. The method as set forth in claim 20, which further comprises: performing a supplementary oxygen plasma treatment after forming the capping layer.

22. The method as set forth in claim 12, which further comprises: performing a nitrification treatment on the multi-level high-dielectric film deposited on the semiconductor substrate before or after performing the oxygen plasma treatment.
